(19) United States
(12) Patent Application Publication
(10) Pub. No.: US 2010/0193864 A1
(43) Pub. Date: Aug. 5, 2010

(54) SEMICONDUCTOR DEVICE

(75) Inventor: Satoru TOKUDA, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/687,365

(22) Filed: Jan. 14, 2010

(30) Foreign Application Priority Data
Feb. 3, 2009 (JP) 2009-022765

(51) Int. Cl. H01L 27/06; H01L 29/78

(52) U.S. Cl. 257/334; 257/E27.014; 257/E29.257

(57) ABSTRACT

A semiconductor device includes a plurality of first gate electrodes that are arranged above a semiconductor substrate in a first direction, and a plurality of second gate electrodes that are arranged above the semiconductor substrate in a second direction. The semiconductor device further includes a first gate lead-out electrode to which the first gate electrodes are connected, a second gate lead-out electrode to which the second gate electrodes are connected, and a third gate lead-out electrode to which the first gate lead-out electrode and the second gate lead-out electrode are connected. In the semiconductor device according to the present invention, a punched pattern is formed in the third gate lead-out electrode.

### INCORPORATION BY REFERENCE

This application is based upon and claims the benefit of priority from Japanese patent application No. 2009-022765, filed on Feb. 3, 2009, the disclosure of which is incorporated herein in its entirety by reference.

### BACKGROUND

1. Field of the Invention

The present invention relates to a semiconductor device, and more particularly, to a semiconductor device that includes gate lead-out electrodes arranged to lead out gate electrodes arranged in grid patterns in vertical and lateral directions.

2. Description of Related Art

A vertical power MOSFET includes a plurality of gate electrodes that are arranged in grid patterns, a cell area where a plurality of transistor cells segmented by the gate electrodes are arranged, and gate lead-out electrodes that lead the gate electrodes to outside the cell area. The gate lead-out electrodes are arranged to surround the cell area so as to apply gate voltage equally to each cell, and the gate electrodes are connected to the gate lead-out electrodes by being led out in vertical and lateral directions.

Japanese Unexamined Patent Application Publication No. 2006-93504 discloses an N channel vertical power MOSFET having a trench gate structure. FIG. 7A shows a plane view of the vertical power MOSFET disclosed in Japanese Unexamined Patent Application Publication No. 2006-93504, and FIG. 7B shows a cross sectional view taken along the line VIIB-VIIB of FIG. 7A.

In FIG. 7A, a plurality of MOSFET cells 102 segmented by the gate electrodes embedded in trenches arranged in grid patterns are arranged in an element area 101. Further, in an outer periphery of the cell area 101, a gate connecting electrode 103 formed of a low-resistance metal (Al) is arranged to surround the cell area 101, and one end thereof is connected to a gate pad electrode 104.

In FIG. 7B, an N-epitaxial layer which is a drain area 111 is formed on an N+ semiconductor substrate 110, and a P type channel layer 116 is formed thereon. A trench part 121 that surrounds an outer periphery of an element area 122 is formed at an end of the channel layer 116. Each gate electrode 118 of each cell 123 is led outside the element area 122 by a gate lead-out electrode 112 to be connected to a gate connecting electrode 113. The gate connecting electrode 113 is connected to the gate pad electrode 104, and applies gate voltage to each cell 123.

As shown in FIG. 7B, the gate electrode 118 is embedded in the trench with a gate oxide film 119 interposed therebetween. An interlayer insulation film 120 is formed on the gate electrode 118. The gate connecting electrode 113 is arranged on the gate lead-out electrode 112 with an interlayer insulation film 114 interposed therebetween so as to be superimposed on the gate lead-out electrode 112, and is connected to the gate lead-out electrode 112 through an opening provided in the interlayer insulation film 114. Further, a source area 117, the channel layer 116, the drain area 111, the gate electrode 118, and the gate oxide film 119 form a vertical MOSFET cell 123.

As shown in FIG. 7B, the gate lead-out electrode 112 is formed above the substrate with an oxide film 115 having larger thickness than the gate oxide film 119 interposed therebetween. Thus, withstand voltage between the gate and the drain can be maintained. In the above-described vertical power MOSFET, most part of the gate lead-out electrode 112 is formed on the oxide film 115 (film thickness of about 1 μm, for example) having relatively large thickness. However, it is not necessary to provide such a thick oxide film 115 in the products with low voltage specifications.

Japanese Unexamined Patent Application Publication No. 11-121741 discloses a semiconductor device in which gate electrodes are arranged in stripe. FIG. 8A shows a vertical power MOSFET disclosed in Japanese Unexamined Patent Application Publication No. 11-121741, and FIG. 8B shows an arrangement of gate electrodes 164.

In FIG. 8A, an N-epitaxial layer which is a drain area 161 is formed on an N+ semiconductor substrate 160, and a P type channel layer 162 is formed thereon. In the channel layer 162, trenches are formed, and gate oxide films 163 and gate electrodes 164 are formed inside the trenches. The plurality of gate electrodes 164 are connected to gate lead-out electrodes 165.

As shown in FIG. 8B, the gate electrodes 164 are formed in stripe, and connected to four gate lead-out electrodes 165.

Japanese Unexamined Patent Application Publication No. 2005-322949 discloses a semiconductor device in which a gate oxide film that covers the inner surface of a trench is also used as an insulation film on the substrate surface and a gate lead-out electrode is arranged thereon. FIG. 9A is a plane view of a vertical power MOSFET disclosed in Japanese Unexamined Patent Application Publication No. 2005-322949, and FIG. 9B is a cross sectional view taken along the line IXB-IXB of FIG. 9A. In FIG. 9A, the interlayer insulation film and the source electrode are omitted to show the relation among gate electrodes 132, a gate lead-out electrode 131, and a gate metal electrode 130 (dotted lines in the drawing).

As shown in FIG. 9A, the gate lead-out electrode 131 is arranged to surround the outer periphery of a cell area where a plurality of MOSFET cells are arranged in grid patterns. Reference symbol 134 is an area where the gate lead-out electrode 131 and the gate electrodes 132 are overlapped with each other, and in this area, the gate electrodes 132 are led out on the substrate to be connected to the gate lead-out electrode 131.

Further, in FIG. 9B, an N type semiconductor layer which is a drain area 141 is formed on an N+ semiconductor substrate 140, and P-channel layer 142 is formed thereon. Inside a trench, a gate oxide film 143 and the gate electrode 132 are formed, and an interlayer insulation film 144 is formed on the gate electrode 132. A source electrode 146 is formed on a MOSFET cell 145. The gate lead-out electrode 131 is formed on the substrate with an oxide film 147 having substantially the same thickness as the gate oxide film 143 interposed therebetween. Further, an interlayer insulation film 148 is formed on the gate lead-out electrode 131, and the gate lead-out electrode 131 is connected to the gate metal electrode 130 through an opening provided in the interlayer insulation film 148.

### SUMMARY

In the vertical power MOSFET shown in FIG. 7, most part of the gate lead-out electrode 112 is arranged on the oxide film 115 having relatively large thickness. Thus, capacitance between a gate and a drain that is produced between the gate lead-out electrode 112 and the N-drain area 111 and capacitance between a gate and a source that is produced between the gate lead-out electrode 112 and the channel layer 116 do not cause a substantial problem.

Meanwhile, in the vertical power MOSFET shown in FIG. 9, the gate lead-out electrode 131 is arranged on the gate oxide film 147 having relatively small thickness (about 10 nm to 100 nm). Thus, in the vertical power MOSFET shown in FIG. 9, the capacitance between the gate and the drain Cgd generated between the gate lead-out electrode 131 and the N type drain layer 141 and the capacitance between the gate and the source Cgs generated between the gate lead-out electrode 131 and the P-channel layer 142 (N+ source area) are so large that it cannot be ignored. The N+ source area and the P-channel layer 142 are connected by the source electrode 146 and have the same potential.

If the parasitic capacitance (sum of Cgd and Cgs) increases, high-speed operation of the vertical MOSFET may be inhibited. Thus, the area of the gate lead-out electrode that is opposed to the channel layer and the lower-layer drain area needs to be reduced as much as possible.

However, when the area of the gate lead-out electrode is reduced, the resistance of the gate lead-out electrode becomes so large that it may be impossible to apply gate voltage equally to each end terminal of the gate electrodes (each MOSFET cell).

An exemplary aspect of the invention is a semiconductor device including a plurality of first gate electrodes that are arranged above a semiconductor substrate in a first direction, a plurality of second gate electrodes that are arranged above the semiconductor substrate in a second direction, a cell area having a plurality of transistor cells arranged therein, the transistor cells being segmented by the first gate electrodes and the second gate electrodes, a first gate lead-out electrode to which the first gate electrodes are connected, a second gate lead-out electrode to which the second gate electrodes are connected, and a third gate lead-out electrode to which the first gate lead-out electrode and the second gate lead-out electrode are connected, in which a punched pattern is formed in the third gate lead-out electrode.

According to the semiconductor device of the present invention, the punched pattern is formed in the third gate lead-out electrode to which the first lead-out electrode and the second lead-out electrode are connected, thereby reducing parasitic capacitance that is generated between a gate and a drain and between a gate and a source of the semiconductor device. Further, the third gate lead-out electrode is relatively apart from each end terminal of the gate electrodes, whereby maintaining uniformity of gate voltages applied to each end terminal of the gate electrodes.

According to the present invention, it is possible to provide a semiconductor device which is capable of reducing parasitic capacitance generated between a gate and a drain, and between a gate and a source while maintaining uniformity of gate voltages applied to each MOSFET cell.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1A shows a plane view of a semiconductor device according to an exemplary embodiment;

FIG. 1B shows an enlarged view of around a corner part of a gate lead-out electrode of the semiconductor device according to the exemplary embodiment;

FIG. 2A shows a cross sectional view taken along the line IIA-IIA of FIG. 1B of the semiconductor device according to the exemplary embodiment;

FIG. 2B shows a cross sectional view taken along the line IIB-IIB of FIG. 1B of the semiconductor device according to the exemplary embodiment;

FIG. 3A shows an enlarged view of the corner part of the gate lead-out electrode of the semiconductor device (when a notched pattern is formed in the gate lead-out electrode of the corner part) according to the exemplary embodiment;

FIG. 3B shows an enlarged view of the corner part of the gate lead-out electrode of the semiconductor device (when a single slit pattern is formed in the gate lead-out electrode of the corner part) according to the exemplary embodiment;

FIG. 4A shows an enlarged view of the corner part of the gate lead-out electrode of the semiconductor device (when a plurality of slit patterns are formed in the gate lead-out electrode of the corner part) according to the exemplary embodiment;

FIG. 4B shows an enlarged view of the corner part of the gate lead-out electrode of the semiconductor device (when a mesh pattern is formed in the gate lead-out electrode of the corner part) according to the exemplary embodiment;

FIG. 5A shows a plane view when the gate lead-out electrode of the corner part is punched over the whole surface in the semiconductor device according to the exemplary embodiment;

FIG. 5B shows an enlarged view of around the corner part of the gate lead-out electrodes of the semiconductor device according to the exemplary embodiment;

FIG. 6A shows a plane view showing the semiconductor device of another aspect of the exemplary embodiment;

FIG. 6B shows an enlarged view of around the corner part of the gate lead-out electrode of the semiconductor device of another aspect of the exemplary embodiment;

FIG. 7A shows a plane view of a semiconductor device disclosed in Japanese Unexamined Patent Application Publication No. 2006-93504;

FIG. 7B shows a cross sectional view taken along the line VIIB-VIIB of FIG. 7A;

FIG. 8A shows an oblique view showing a vertical power MOSFET disclosed in Japanese Unexamined Patent Application Publication No. 11-121741;

FIG. 8B shows arrangement of gate electrodes of the vertical power MOSFET disclosed in Japanese Unexamined Patent Application Publication No. 11-121741;

FIG. 9A shows a plane view of a semiconductor device disclosed in Japanese Unexamined Patent Application Publication No. 2005-322949; and

FIG. 9B shows a cross sectional view taken along the line IXB-IXB of FIG. 9A.

### DETAILED DESCRIPTION OF THE EXEMPLARY EMBODIMENTS

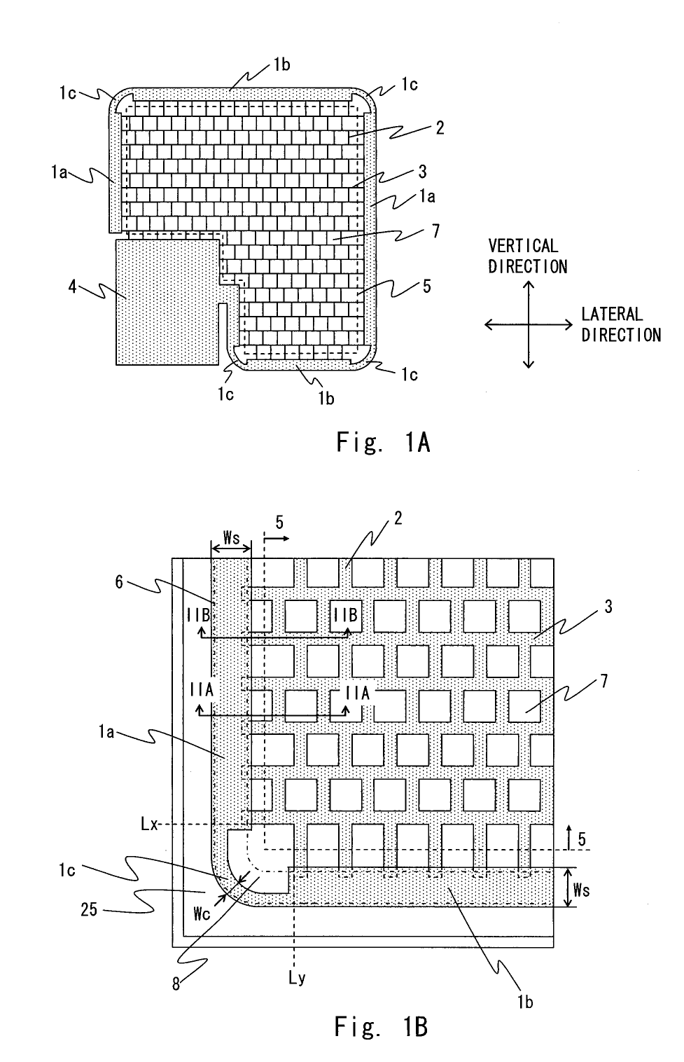

Hereinafter, the exemplary embodiment of the present invention will be described with reference to the drawings. FIG. 1A shows a plane view of a semiconductor device according to the exemplary embodiment. FIG. 1B shows an enlarged view of around a corner part of a gate lead-out electrode shown in FIG. 1A. In FIGS. 1A and 1B, interlayer insulation films and source electrodes are omitted for the purpose of illustrating relation among gate electrodes 2 and 3, gate lead-out electrodes 1a, 1b, 1c, and a gate metal electrode 6 (dotted lines in the drawings).

The semiconductor device according to the exemplary embodiment includes first gate electrodes 2 arranged above a semiconductor substrate in a first direction (vertical direction), and second gate electrodes 3 arranged above the semiconductor substrate in a second direction (lateral direction). The semiconductor device further includes a cell area 5 where a plurality of transistor cells 7 segmented by the first gate electrodes 2 and the second gate electrodes 3 are arranged, first gate lead-out electrodes 1b to which the first gate electrodes 2 are connected, and second gate lead-out electrodes 1a to which the second gate electrodes 3 are connected. The semiconductor device further includes third gate lead-out electrodes 1c to which the first gate lead-out electrodes 1b and the second gate lead-out electrodes 1a are connected. In the semiconductor device according to the exemplary embodiment, a punched pattern 8 is formed in one of the third gate lead-out electrodes 1c. Hereinafter, description will be made in detail.

The semiconductor device according to the exemplary embodiment will be described taking an example of an N channel vertical power MOSFET having a trench-gate structure. FIG. 1A shows arrangement of the gate lead-out electrodes 1a, 1b, 1c and the gate electrodes 2 and 3 of the vertical power MOSFET according to the exemplary embodiment. Grid lines shown in FIG. 1A show gate electrodes arranged in trenches. Further, as shown in FIG. 1A, a first direction that forms grids is called vertical direction, and a direction that is perpendicular to the first direction (second direction) is called lateral direction. Note that the first direction and the second direction are typically perpendicular to each other, although it is not necessary.

In FIG. 1A, the gate electrodes 2 arranged in the vertical direction and the gate electrodes 3 arranged in the lateral direction are connected to each other and arranged in grid patterns. Each end of the gate electrodes 2 arranged in the vertical direction is connected to the gate lead-out electrodes 1b extending in the lateral direction. Further, each end of the gate electrodes 3 arranged in the lateral direction is connected to the gate lead-out electrodes 1a extending in the vertical direction. The gate lead-out electrode 1a extending in the vertical direction and the gate lead-out electrode 1b extending in the lateral direction are connected in the gate lead-out electrode 1C at corner part. Polysilicon may be used, for example, as the gate electrodes and the gate lead-out electrodes. Each of the gate lead-out electrodes 1a, 1b, and 1c is formed to surround the cell area 5, and each end is connected to a gate pad 4. Further, the cell area 5 (dashed line area) is the area where a large number of transistor cells (MOSFET cells) 7 segmented by the gate electrodes 2 and 3 arranged in grid patterns are arranged.

FIG. 1B shows an enlarged view of around a corner part 25 of the gate lead-out electrodes. As is similar to FIG. 1A, the gate electrodes 2 arranged in the vertical direction and the gate electrodes 3 arranged in the lateral direction are connected together and arranged in grid patterns. Further, each end of the gate electrodes is connected to the gate lead-out electrodes 1a and 1b.

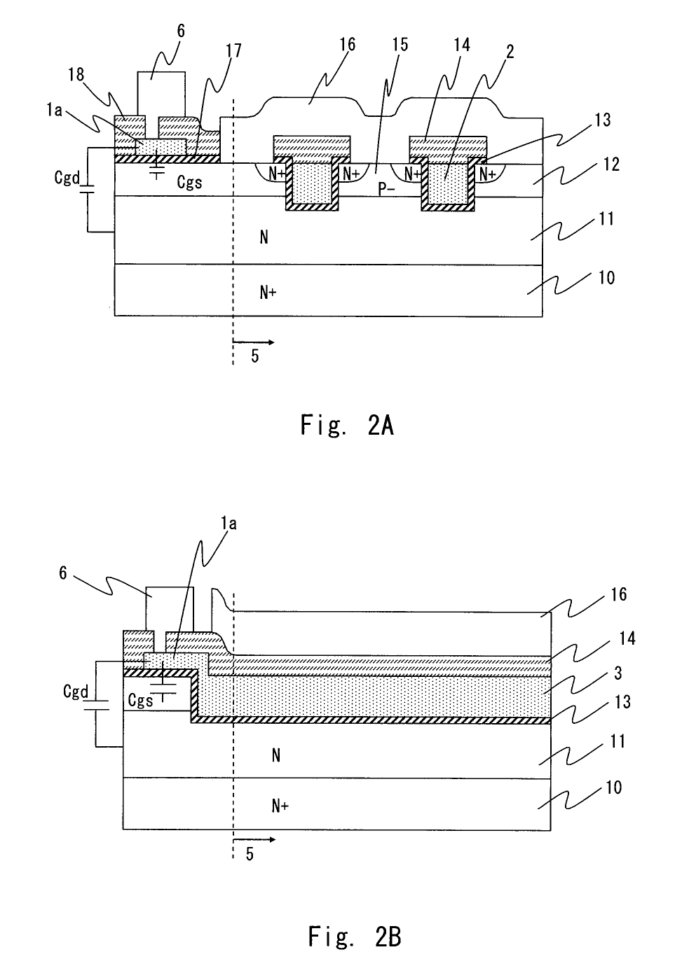

FIG. 2A shows a cross sectional view taken along the line IIA-IIA of FIG. 1B. As shown in FIG. 2A, an N type semiconductor layer 11 which is a drain layer is formed on an N+ semiconductor layer 10, and a P-channel layer 12 is formed thereon. Further, in trenches formed in the cell area 5, gate insulation films (gate oxide films) 13 and the gate electrodes 2 are formed. Interlayer insulation films 14 are formed on the gate electrodes 2. Further, source electrodes 16 are formed on each transistor cell 15.

On the other hand, outside the cell area 5, an insulation film (gate insulation film) 17 is formed on the P-channel layer 12 and the gate lead-out electrode 1a is formed thereon. The gate lead-out electrode 1a is connected to the gate metal electrode 6 through an opening provided in the interlayer insulation film 18. In FIG. 1B, the gate metal electrode 6 arranged on the gate lead-out electrode 1a is shown in dotted lines.

FIG. 2B shows a cross sectional view taken along the line IIB-IIB shown in FIG. 1B. As shown in FIG. 2B, the N type semiconductor layer 11 which is a drain layer is formed on the N+ semiconductor layer 10. Further, the gate insulation film 13 is formed on the N type semiconductor layer 11, and the gate electrode 3 is formed on the gate insulation film 13. The gate electrode 3 is connected to the gate lead-out electrode 1a outside the cell area 5. At this time, the gate electrode 3 and the gate lead-out electrode 1a are formed in and outside the cell area 5. In short, the gate electrodes 2 and the gate lead-out electrode 1a shown in FIG. 2A are continuously and integrally formed.

Similarly, the gate insulation film 13 is formed in and outside the cell area 5. In short, the gate insulation film 13 and the insulation film 17 shown in FIG. 2A are continuously and integrally formed. Similarly, the interlayer insulation film 14 is formed in and outside the cell region 5. In short, the interlayer insulation film 14 and the interlayer insulation film 18 shown in FIG. 2A are continuously and integrally formed.

As shown in FIGS. 2A and 2B, the gate lead-out electrode 1a is arranged on the gate insulation film 13 having relatively small thickness. Thus, capacitance between a gate and a drain Cgd that is generated between the gate lead-out electrode 1a and the N type drain layer 11 and capacitance between a gate and a source Cgs that is generated between the gate lead-out electrode 1a and the P-channel layer 12 are so large that they cannot be ignored.

In the semiconductor device according to the exemplary embodiment, the punched pattern 8 is formed in the gate lead-out electrode 1c of the corner part 25 to which the gate lead-out electrode 1a and the gate lead-out electrode 1b are connected as shown in FIG. 1B in order to reduce the parasitic capacitance Cgd, Cgs. In other words, the area of the gate lead-out electrode in the corner part 25 can be reduced by making a width Wc of the gate lead-out electrode 1c of the corner part 25 smaller than a width Ws of the gate lead-out electrodes 1a, 1b. Accordingly, the electrode area where the gate lead-out electrode 1c is opposed to the drain area or the channel layer can be reduced, thereby reducing the parasitic capacitance Cgd, Cgs.

Now, the corner part 25 of the gate lead-out electrode is the area that is segmented by an extending line of the outermost gate electrode in the lateral direction (Lx shown in FIG. 1B) and an extending line of the outermost gate electrode in the vertical direction (Ly shown in FIG. 1B) of the gate electrodes arranged in the grid patterns. Now, the width Wc of the gate lead-out electrode 1c may be, for example, about 10 to 50% of the width Ws of the gate lead-out electrodes 1a and 1b.

On the other hand, the current path area is reduced when the punched pattern 8 is provided in the gate lead-out electrode 1c of the corner part 25, which slightly increases the gate resistance as there is a trade-off relationship between them. However, also on the punched pattern 8, the gate metal electrode 6 that is formed of the low-resistance metal having quite small resistance ratio compared with the polysilicon is continuously formed with the same width. Further, this gate metal electrode 6 is connected to the gate lead-out electrode 1a as shown in FIG. 2B. Thus, in this case, even when the resistance of the gate lead-out electrode is somewhat increased, no substantial problem is caused since the resistance of the gate metal electrode 6 that is connected is low.

Further, as the corner area outside the cell area 5 is relatively apart from each end terminal of the gate electrodes, uniformity of the gate voltages can be maintained even when the plane pattern of the gate lead-out electrodes of the corner area is changed.

As stated above, according to the exemplary embodiment of the present invention, it is possible to provide a semiconductor device that is capable of reducing the parasitic capacitance between the gate and the drain, and the gate and the source while maintaining the uniformity of the gate voltages applied to each of the transistor cells.

Note that the punched pattern of the gate lead-out electrode in the corner part of the semiconductor device according to the exemplary embodiment may be any punched pattern as long as the capacitance in the corner area of the gate lead-out electrode is reduced. More specific examples will be described below.

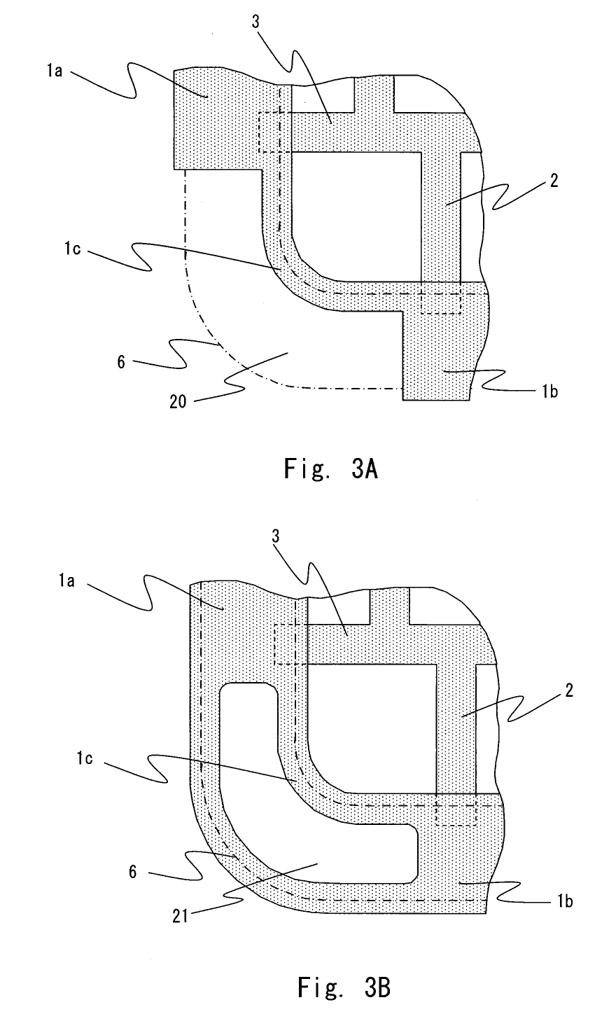

FIG. 3A is a diagram showing an example when a notched pattern is formed in the gate lead-out electrode 1c in the corner part of the semiconductor device according to the exemplary embodiment. Note that the same components as FIGS. 1 and 2 are denoted by the same reference symbols. In FIG. 1B, the punched pattern 8 is the notched pattern formed in the cell area 5 side of the gate lead-out electrode 1c. However, in FIG. 3A, a notched pattern 20 is formed in the place different from the case of FIG. 1B, which is the area opposite side to the cell area 5 of the gate lead-out electrode 1c.

Also in FIG. 3B, the example is shown when the notched pattern is formed in the gate lead-out electrode 1c in the corner part of the semiconductor device according to the exemplary embodiment. In FIG. 3B, a single slit pattern 21 is formed in the gate lead-out electrode 1c.

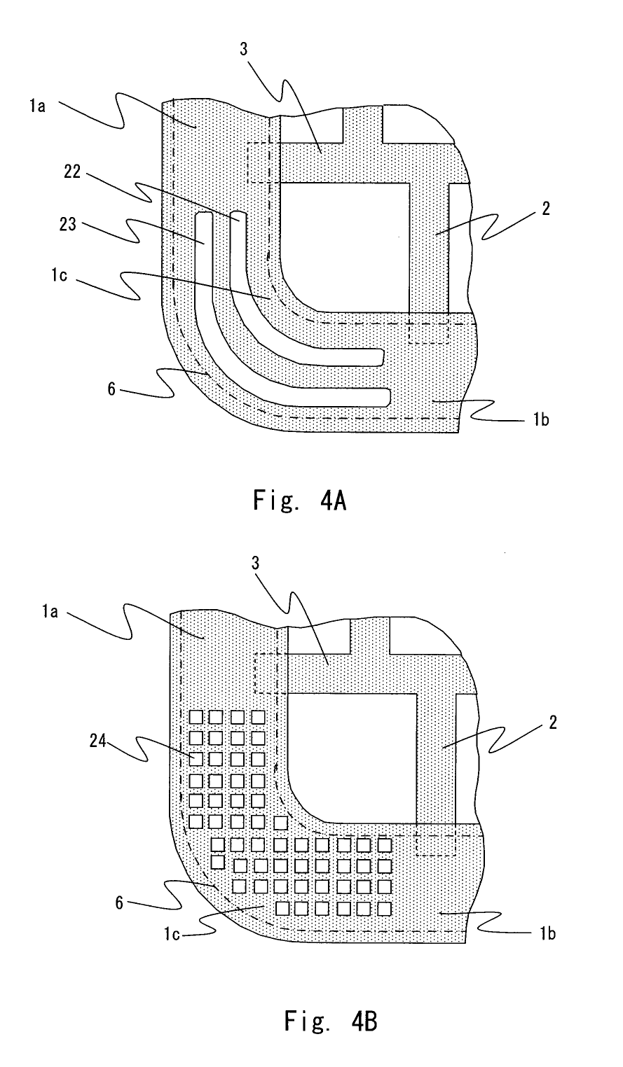

Also in FIG. 4A, the example is shown when the notched pattern is formed in the gate lead-out electrode 1c in the corner part of the semiconductor device according to the exemplary embodiment. In FIG. 4A, a plurality of slit patterns 22 and 23 are formed in the lead-out electrode 1c.

Also in FIG. 4B, the example is shown when the notched pattern is formed in the gate lead-out electrode 1c in the corner part of the semiconductor device according to the exemplary embodiment. In FIG. 4B, a mesh pattern 24 is formed in the lead-out electrode 1c.

The gate lead-out electrode 1c in the corner part is formed to have the above configuration, whereby it is possible to reduce the parasitic capacitance generated between the gate and the drain, and the gate and the source while maintaining the uniformity of the gate voltages applied to each transistor cell.

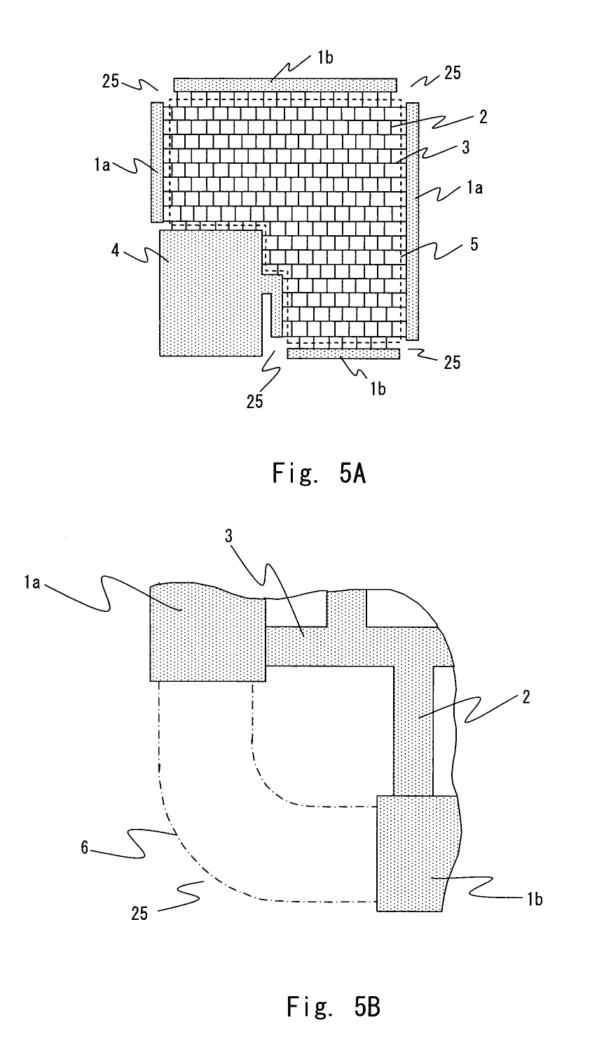

Next, the pattern of the gate lead-out electrode in the corner part when the resistances of the gate lead-out electrodes and the gate electrodes do not cause a substantial problem will be described with reference to FIGS. 5A and 5B. FIG. 5A is a plane view showing the semiconductor device according to the exemplary embodiment. In FIG. 5A, the gate lead-out electrodes in the corner part are punched over the whole surface. FIG. 5B is an enlarged view of around a corner part of the gate lead-out electrode. Note that the semiconductor device shown in FIGS. 5A and 5B is basically similar to that shown in FIGS. 1A and 1B except that the gate lead-out electrodes in the corner part are punched over the whole surface. Further, the same components as the semiconductor device shown in FIGS. 1A and 1B are denoted by the same reference symbols.

Each corner area 25 shown in FIG. 5A has the configuration in which the gate lead-out electrodes 1a extending in the vertical direction and the gate lead-out electrodes 1b extending in the lateral direction are not connected, as shown in FIG. 5B. As the gate lead-out electrode 1c is not provided in the corner part 25, the parasitic capacitance generated between the gate and the drain, and the gate and the source can be reduced.

On the other hand, when the gate lead-out electrode 1c is not provided in the corner part 25, the resistance of the gate lead-out electrode is higher than the case in which the gate lead-out electrode 1c is provided (FIG. 1A and the like). This may make the gate voltages applied to each transistor cell non-uniform.

Although the gate lead-out electrode is divided in the corner area, the gate metal electrode 6 is continuously provided with the same width as that in the upper layer of the gate lead-out electrodes 1a and 1b also on the corner areas. Note that the gate metal electrode 6 is a low-resistance metal having extremely small resistivity. As shown in FIG. 2B, the gate metal electrode 6 is connected to the gate lead-out electrodes 1a and 1b through an opening provided in the interlayer insulation film 14. As the gate lead-out electrode 1a extending in the vertical direction and the gate lead-out electrode 1b extending in the lateral direction are connected through a low-resistance gate metal electrode 6, the resistance of the gate lead-out electrode is small.

From the above description, it becomes possible to reduce the parasitic capacitance generated between the gate and the drain, and the gate and the source while maintaining uniformity of the gate voltages applied to each of the transistor cells also in the exemplary embodiment shown in FIG. 5A.

Although the example in which the gate lead-out electrode 1c is not arranged in each of the four corner areas 25 has been shown in FIG. 5A, the number and the position of the corner area 25 in which the gate lead-out electrode 1c is not arranged can be arbitrarily set.

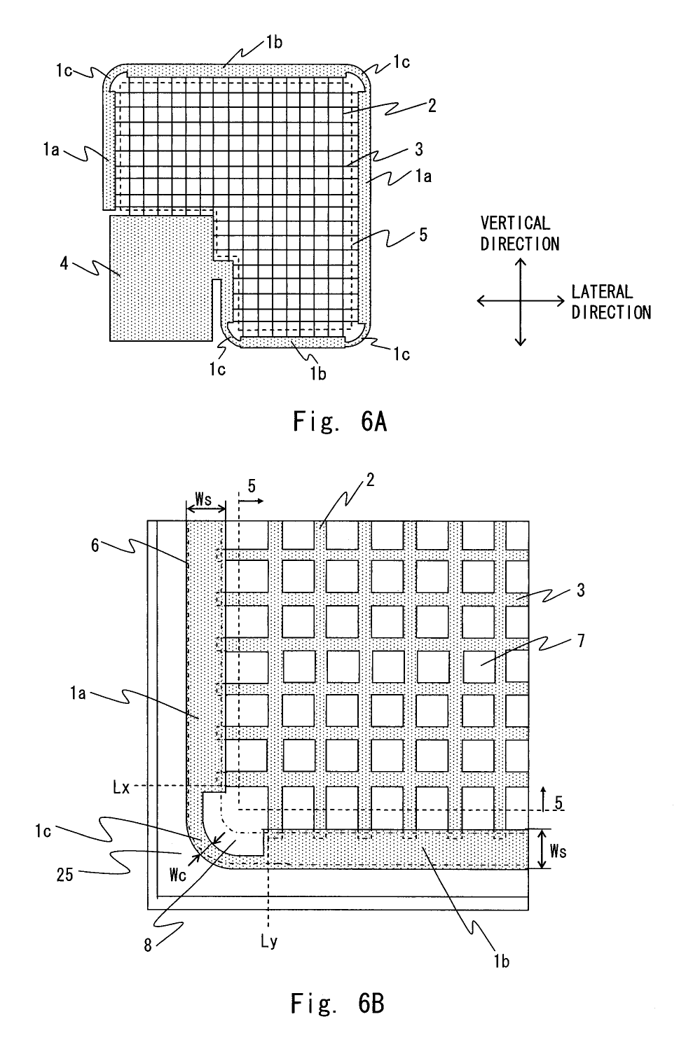

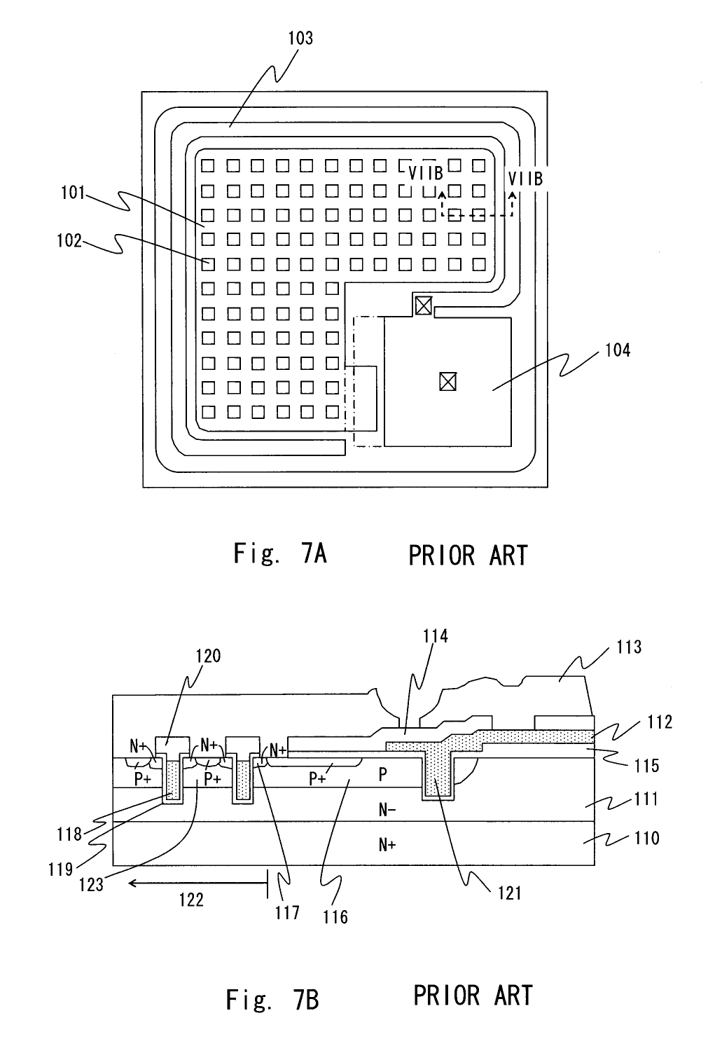

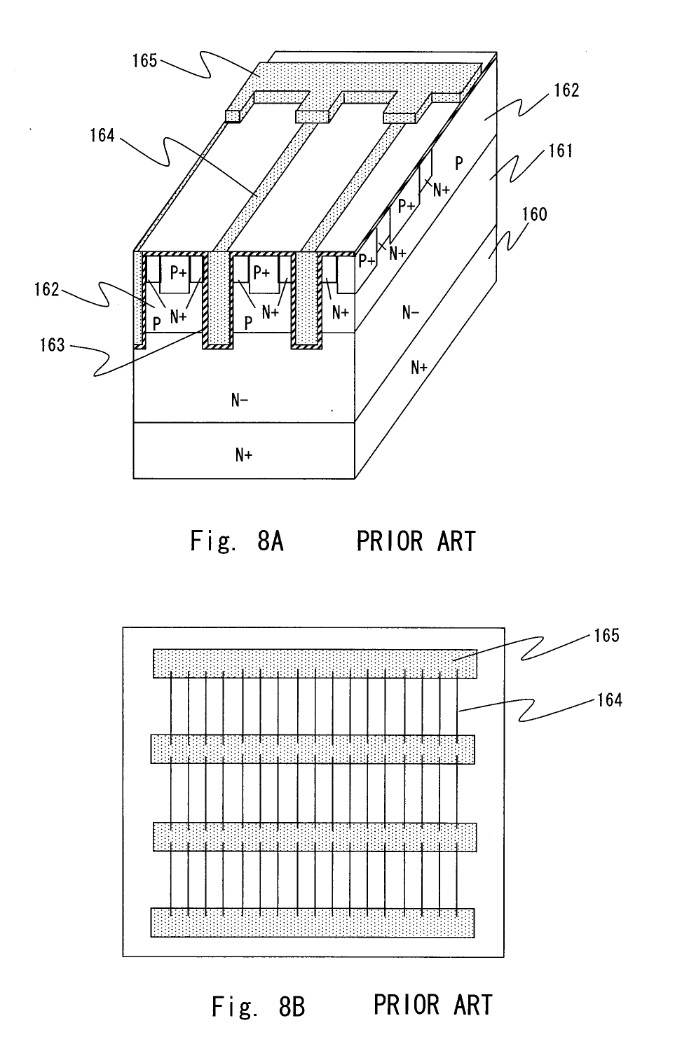

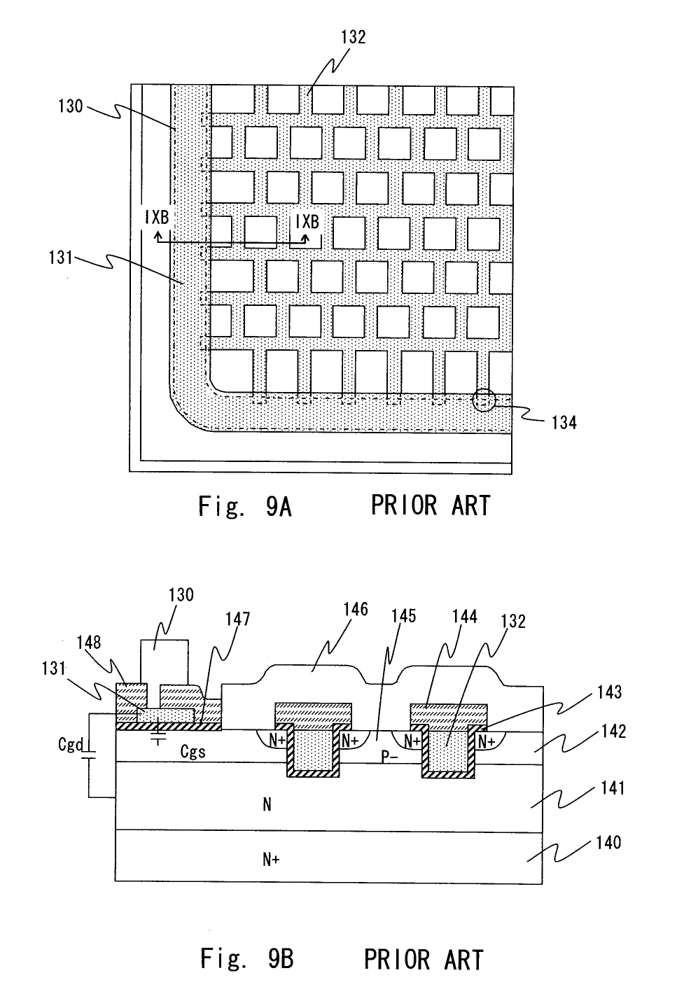

Further, in the exemplary embodiment, description has been made of the semiconductor device in which the gate electrodes 2 and 3 are arranged in FIG. 1. However, even in the semiconductor device in which the gate electrodes 2 and 3 are arranged in grid patterns as shown in FIG. 6, the similar advantage according to the exemplary embodiment can be obtained. As FIG. 6 is the same to FIG. 1 except for the arrangement of the gate electrodes 2 and 3, detailed description will be omitted.

When the semiconductor device according to the exemplary embodiment is manufactured, it is needed to only change the mask pattern to etch the gate lead-out electrodes (polysilicon layers) in the process of forming the gate lead-out electrodes. Thus, it is not needed to increase the number of processes.

Further, in the exemplary embodiment, the semiconductor device having the trench-gate structure has been described as an example. However, it is not limited to this example as long as the semiconductor device is the one in which the gate electrodes are arranged on the surface of the substrate. Further, although description has been made with the N-channel MOSFET in the exemplary embodiment as an example, a P-channel MOSFET can attain the similar advantage. Furthermore, although description has been made with the vertical power MOSFET in the exemplary embodiment as an example, it is not limited to this example but may be applied also in IGBT, for example.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device comprising:
a plurality of first gate electrodes that are arranged above a semiconductor substrate in a first direction;
a plurality of second gate electrodes that are arranged above the semiconductor substrate in a second direction;
a cell area having a plurality of transistor cells arranged therein, the transistor cells being segmented by the first gate electrodes and the second gate electrodes;
a first gate lead-out electrode to which the first gate electrodes are connected;
a second gate lead-out electrode to which the second gate electrodes are connected; and
a third gate lead-out electrode to which the first gate lead-out electrode and the second gate lead-out electrode are connected, wherein
a punched pattern is formed in the third gate lead-out electrode.

2. The semiconductor device according to claim 1, wherein the punched pattern is a notched pattern formed in a side of the cell area of the third gate lead-out electrode.

3. The semiconductor device according to claim 1, wherein the punched pattern is a notched pattern formed in an area opposite to the side of the cell area of the third gate lead-out electrode.

4. The semiconductor device according to claim 1, wherein the punched pattern is a single slit pattern.

5. The semiconductor device according to claim 1, wherein the punched pattern is a plurality of slit patterns.

6. The semiconductor device according to claim 1, wherein the punched pattern is a mesh pattern.

7. The semiconductor device according to claim 1, wherein the punched pattern is a pattern formed by punching a whole surface of the third gate lead-out electrode.

8. The semiconductor device according to claim 1, wherein the first and second gate lead-out electrodes are arranged on an insulation film having the same thickness as that of a gate insulation film arranged below the first and second gate electrodes.

9. The semiconductor device according to claim 1, wherein the first and second gate lead-out electrodes are connected to a gate metal electrode through an opening of an interlayer insulation film formed on the first and second gate lead-out electrodes, the gate metal electrode being continuously formed with the same width in an area corresponding to an area where the first to third gate lead-out electrodes are formed.

10. The semiconductor device according to claim 1, wherein the transistor cells form a vertical power MOSFET.
